(19) United States
(12) Patent Application Publication
(10) Pub. No.: US 2026/0156963 A1
(43) Pub. Date: Jun. 4, 2026

(54) SOLAR CELL AND PHOTOVOLTAIC MODULE

(71) Applicant: BYD COMPANY LIMITED, Shenzhen (CN)

(72) Inventors: Xue LUO, Shenzhen (CN); Peng DONG, Shenzhen (CN); Yuebin YU, Shenzhen (CN); Canlin OU, Shenzhen (CN); Wei ZHOU, Shenzhen (CN)

(73) Assignee: BYD COMPANY LIMITED, Shenzhen (CN)

(21) Appl. No.: 19/457,339

(22) Filed: Jan. 23, 2026

Related U.S. Application Data
(63) Continuation of application No. PCT/CN2024/101787, filed on Jun. 27, 2024.

(30) Foreign Application Priority Data
Jul. 24, 2023 (CN) 202321970187.9

(51) Int. Cl. H10F 77/20; H10F 77/122; H10F 77/164; H10F 77/30; H10F 77/70

(52) U.S. Cl. CPC H10F 77/211; H10F 77/315; H10F 77/122; H10F 77/1642; H10F 77/703

(57) ABSTRACT

A solar cell comprises a first anti-reflection layer, a passivation layer, an electrode emission layer, a silicon-based bottom layer, a tunneling oxide layer, a doped polycrystalline silicon layer and a second anti-reflection layer, which are stacked, wherein a first electrode and a second electrode are respectively provided on the first anti-reflection layer and the second anti-reflection layer, a low-work-function conductive layer is provided in the doped polycrystalline silicon layer, and the low-work-function conductive layer is adjacent to the second electrode.

### CROSS-REFERENCE TO RELATED APPLICATIONS

This application claims the benefit of International Application No. PCT/CN 2024/101787, filed on Jun. 27, 2024, which claims priority to Chinese Patent Application No. 202321970187.9, filed with the China National Intellectual Property Administration on Jul. 24, 2023 and entitled “SOLAR CELL AND PHOTOVOLTAIC MODULE.” The disclosures of the prior applications are incorporated herein by reference in their entirety.

### TECHNICAL FIELD

This application relates to the field of solar cells, and more particularly, to a solar cell and a photovoltaic module.

### BACKGROUND

A solar cell is a semiconductor device that directly converts sunlight into electricity. Currently, in addition to conventional crystalline silicon solar cells, solar cells with a tunnel passivated contact structure are increasingly attracting market attention due to higher photovoltaic conversion efficiency. Such a passivated contact structure generally includes a tunneling oxide layer and a doped polycrystalline silicon layer that are stacked, and the doped polycrystalline silicon layer is in direct contact with a metal electrode, to form a current path. However, the metal electrode is generally prepared by using a high-temperature paste screen printing process. A high-temperature metal paste easily burns through the doped polycrystalline silicon layer, potentially damaging a cell structure.

### SUMMARY

In view of this, a low-work-function conductive layer is added to a tunnel passivated contact structure in a solar cell provided in this application, to address a problem that may be caused by a high-temperature metal paste.

According to a first aspect of this application, a solar cell is provided, including a first anti-reflection layer, a passivation layer, an electrode emission layer, a silicon-based bottom layer, a tunneling oxide layer, a doped polycrystalline silicon layer, and a second anti-reflection layer, which are stacked, where a first electrode and a second electrode are respectively provided on the first anti-reflection layer and the second anti-reflection layer; and a low-work-function conductive layer is provided in the doped polycrystalline silicon layer, and the low-work-function conductive layer is in direct contact with the second electrode. In an embodiment, a low-work-function conductive layer is provided in the doped polycrystalline silicon layer, and the low-work-function conductive layer is not in direct contact with the second electrode. In an embodiment, a low-work-function conductive layer is provided in the doped polycrystalline silicon layer, and the low-work-function conductive layer is adjacent to the second electrode (either in direct contact or not in direct contact to the second electrode).

The low-work-function conductive layer has a field passivation function and can effectively collect and transport electrons. In addition, because the low-work-function conductive layer is in direct contact with or not in direct contact with the second electrode, the low-work-function conductive layer serves as a primary recipient for a high-temperature metal paste during cell preparation, thereby potentially alleviating a burnthrough problem caused by the metal paste.

Optionally, a material of the low-work-function conductive layer is selected from Ca, Mg, Ba, Ga, Li, Ce, Tb, Gd, Y, Nd, Lu, Th, Sc, La, U, or Hf.

Optionally, a thickness of the doped polycrystalline silicon layer ranges from 10 nm to 120 nm.

Optionally, a thickness of the low-work-function conductive layer is less than a thickness of the doped polycrystalline silicon layer.

Optionally, the thickness of the low-work-function conductive layer ranges from 2 nm to 100 nm.

Optionally, a projection of the second electrode in a first direction on a plane in which an end surface that is of the low-work-function conductive layer and that is away from the tunneling oxide layer is located falls within the end surface that is of the low-work-function conductive layer and that is away from the tunneling oxide layer; and the first direction points from the second anti-reflection layer to the first anti-reflection layer.

Optionally, the projection of the second electrode in the first direction on the plane in which the end surface that is of the low-work-function conductive layer and that is away from the tunneling oxide layer is located coincides with the end surface that is of the low-work-function conductive layer and that is away from the tunneling oxide layer; and the first direction points from the second anti-reflection layer to the first anti-reflection layer.

Optionally, the second electrode runs through the second anti-reflection layer and protrudes relative to a surface that is of the second anti-reflection layer and that faces away from the doped polycrystalline silicon layer.

Optionally, the second electrode runs through the second anti-reflection layer, and extends into the doped polycrystalline silicon layer and is in direct contact with or not in direct contact with the low-work-function conductive layer.

Optionally, a material of the tunneling oxide layer includes at least one of silicon oxide, titanium oxide, and aluminum oxide.

Optionally, a material of the passivation layer includes at least one of silicon oxide, silicon nitride, silicon oxynitride, and aluminum oxide.

Optionally, a material of the first anti-reflection layer includes at least one of silicon oxide, silicon nitride, and silicon oxynitride; and a material of the second anti-reflection layer includes at least one of silicon oxide, silicon nitride, and silicon oxynitride.

Optionally, the low-work-function conductive layer is in direct contact with or not in direct contact with the tunneling oxide layer.

Optionally, the silicon-based bottom layer is an N-type silicon-based bottom layer, and the doped polycrystalline silicon layer is a phosphorus-doped polycrystalline silicon layer.

According to a second aspect of this application, a photovoltaic module is provided. The photovoltaic module includes the solar cell provided in the first aspect of this application.

Optionally, the photovoltaic module further includes a front cover plate, a rear cover plate, a first encapsulant film, and a second encapsulant film, the front cover plate is bonded to a side of the solar cell by using the first encapsulant film, and the rear cover plate is bonded to another side of the solar cell by using the second encapsulant film.

With the solar cell described above, the photovoltaic module has high photoelectric conversion efficiency and high market competitiveness.

### BRIEF DESCRIPTION OF DRAWINGS

To describe the technical solutions in the embodiments of this application more clearly, the following briefly describes the accompanying drawings required for the embodiments. The accompanying drawings in the following descriptions show some embodiments of this application, and a person of ordinary skill in the art may obtain other accompanying drawings from these accompanying drawings without creative efforts.

FIG. 1 is a schematic diagram of a cross-sectional structure of a solar cell according to an embodiment of this application;

FIG. 2 is a schematic diagram of a cross-sectional structure of a solar cell according to another embodiment of this application;

FIG. 3 is a schematic diagram of a cross-sectional structure of a solar cell according to still another embodiment;

FIG. 4 is a schematic diagram of a cross-sectional structure of a solar cell according to yet another embodiment; and

FIG. 5 is a schematic diagram of a structure of a photovoltaic module according to an embodiment of this application.

Reference numerals: 100—solar cell; 11—first anti-reflection layer; 12—passivation layer; 20—electrode emission layer; 30—silicon-based bottom layer; 40—tunneling oxide layer; 50—doped polycrystalline silicon layer; 60—second anti-reflection layer; 70—first electrode; 80—second electrode; 90—low-work-function conductive layer; 1000—photovoltaic module; 1002—front cover plate; 1004—rear cover plate; 1006—first encapsulant film; and 1008—second encapsulant film.

### DESCRIPTION OF EMBODIMENTS

The technical solutions in the embodiments of this application are described below with reference to the accompanying drawings in the embodiments of this application. The described embodiments are some, rather than all, of the embodiments of this application. All other embodiments obtained by a person of ordinary skill in the art based on the embodiments of this application without creative efforts shall fall within the protection scope of this application.

It should be understood that, in the descriptions of the implementations of this application, the terms “first” and “second” are used for description purposes, and should not be understood as indicating or implying relative importance or implicitly indicating a quantity of technical features indicated. Therefore, features defined with “first” and “second” may explicitly or implicitly include one or more of the features. In the descriptions of the implementations of this application, “a plurality of” means two or more, unless otherwise explicitly defined.

In the descriptions of the implementations of this application, it should be noted that, unless otherwise specified or limited, terms “communicate” and “connect” should be understood in a broad sense, for example, may be a fixed connection, a detachable connection, or an integrated connection, may be a mechanical connection, an electrical connection, or mutual communication, may be a direct connection or an indirect connection implemented by using an intermediate medium, or may be communication between two elements or an interaction relationship between two elements. A person of ordinary skill in the art may understand meanings of the foregoing terms in the implementations of this application based on the context.

The present disclosure provides many different implementations or examples for implementing different structures in the implementations of this application. To simplify the disclosure of the implementations of this application, components and settings of examples are described herein. The components and the settings are examples and are not intended to limit this application. In addition, reference numerals and/or reference letters may be repeated in different examples in the implementations of this application for simplicity and clarity purposes, and do not indicate a relationship between the various implementations and/or settings discussed. In addition, the implementations of this application provide examples of various processes and materials, but a person of ordinary skill in the art may be aware of application of other processes and/or use of other materials.

In the descriptions of this specification, descriptions referring to the terms “one implementation”, “some implementations”, “examples”, “specific examples”, or “some examples” mean that features, structures, materials, or characteristics described with reference to this implementation or example are included in at least one implementation or example of this application. In this specification, illustrative expressions of the foregoing terms do not necessarily refer to a same implementation or example. In addition, the described features, structures, materials, or characteristics may be combined in an appropriate manner in any one or more implementations or examples.

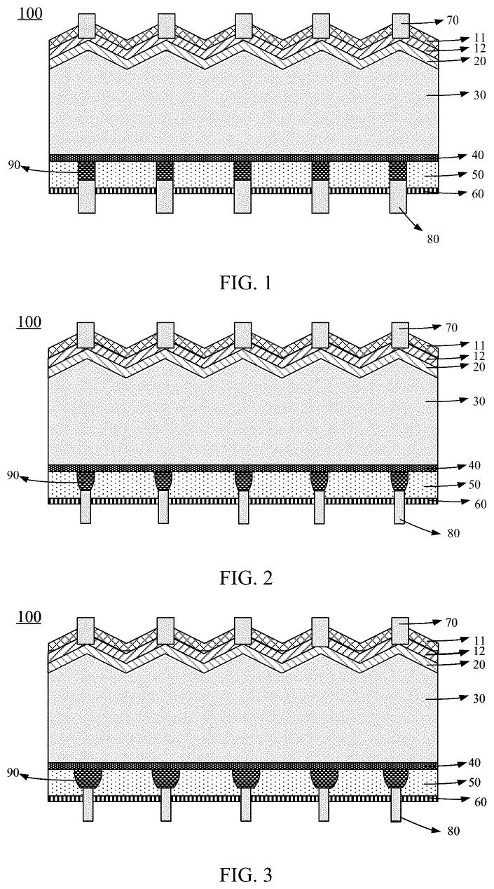

Referring to FIG. 1, an embodiment of this application provides a solar cell 100, including a first anti-reflection layer 11, a passivation layer 12, an electrode emission layer 20, a silicon-based bottom layer 30, a tunneling oxide layer 40, a doped polycrystalline silicon layer 50, and a second anti-reflection layer 60, which are stacked. A first electrode 70 and a second electrode 80 are respectively provided on the first anti-reflection layer 11 and the second anti-reflection layer 60. That is, the first electrode 70 is provided on the first anti-reflection layer 11, and the second electrode 80 is provided on the second anti-reflection layer 60. In this embodiment of this application, that the first electrode 70 is provided on the first anti-reflection layer 11 means that the first electrode 70 may be stacked on a surface of the first anti-reflection layer 11, or the first electrode 70 runs through/is partially embedded into and does not run through the first anti-reflection layer 11 and protrudes relative to a surface that is of the first anti-reflection layer 11 and that faces away from the passivation layer 12. In this embodiment of this application, that the second electrode 80 is provided on the second anti-reflection layer 60 means that the second electrode 80 runs through the second anti-reflection layer 60 and protrudes relative to a surface that is of the second anti-reflection layer 60 and that faces away from the doped polycrystalline silicon layer 50. Further, the first electrode 70 may alternatively run through the first anti-reflection layer 11 and extend into the passivation layer 12. A specific position in the solar cell 100 to which the first electrode 70 extends is not limited in this application, and may be selected by a person of ordinary skill in the art according to an actual requirement, provided that photovoltaic conversion can be completed.

In this embodiment of this application, a low-work-function conductive layer 90 is provided in the doped polycrystalline silicon layer 50. The low-work-function conductive layer 90 is in direct contact with the second electrode 80. In this embodiment of this application, that a low-work-function conductive layer 90 is provided in the doped polycrystalline silicon layer 50 includes, but is not limited to, the following case: The low-work-function conductive layer 90 extends in a direction from a surface of the tunneling oxide layer 40 to the second electrode 80. In addition, a surface of the low-work-function conductive layer 90 other than an end surface in contact with the second electrode 80 and an end surface in contact with the tunneling oxide layer 40 is surrounded by the doped polycrystalline silicon layer 50. In an embodiment, the low-work-function conductive layer 90 is not in direct contact with the second electrode 80. An intermediate layer may exist between the low-work-function conductive layer 90 and the second electrode 80.

In this application, the low-work-function conductive layer 90 is added to a tunnel passivated contact structure. The low-work-function conductive layer 90 has a field passivation function and can effectively collect free electrons. Therefore, smooth and efficient electron transport in the solar cell can be achieved, and normal operation of the solar cell is facilitated. In addition, in a preparation process of a tunnel passivated contact solar cell, a high-temperature metal paste is printed on a surface of the second anti-reflection layer 60 (that is, a back anti-reflection layer of the solar cell), and the metal paste burns through the second anti-reflection layer 60 to form the second electrode 80, so that the second electrode 80 is in direct contact with the doped polycrystalline silicon layer 50 to collect the electrons. A problem that the metal paste burns through the doped polycrystalline silicon layer 50 can occur in the foregoing process. In this application, because the low-work-function conductive layer 90 in the cell is in direct contact with the second electrode 80, the low-work-function conductive layer 90 serves as a primary recipient for the high-temperature metal paste during cell preparation, thereby potentially alleviating a burnthrough problem caused by the metal paste.

Generally, in a process of using the solar cell, a side of the first anti-reflection layer 11 is a front surface (facing sunlight) of the solar cell, and a side on which the tunnel passivated contact structure is provided is a back surface of the solar cell. Therefore, the first anti-reflection layer 11 is also referred to as a “front anti-reflection layer”, and the second anti-reflection layer 60 is also referred to as a “back anti-reflection layer”.

In addition, in related technologies, to prevent the metal paste from burning through the doped polycrystalline silicon layer, a thickness of the doped polycrystalline silicon layer may be increased in a process (generally, in related technologies, the thickness of the doped polycrystalline silicon layer in the tunnel passivated contact structure is greater than 120 nm). In this case, a parasitic absorption phenomenon of the cell may be increased, and photoelectric conversion efficiency of the cell may be affected. Iin the solar cell 100 provided in this application, the thickness of the doped polycrystalline silicon layer 50 does not need to be additionally increased due to the existence of the low-work-function conductive layer 90. In the solar cell 100 in this application, the thickness of the doped polycrystalline silicon layer 50 may be less than or equal to about 120 nm, so that the parasitic absorption effect of the doped polycrystalline silicon layer 50 can be reduced, thereby improving photoelectric conversion efficiency of the solar cell 100.

In some implementations of this application, a thickness of the doped polycrystalline silicon layer 50 ranges from about 10 nm to about 120 nm. For example, the thickness of the doped polycrystalline silicon layer 50 may be about 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, or 120 nm. The thickness of the doped polycrystalline silicon layer 50 is controlled within the foregoing range to effectively reduce the parasitic absorption effect, and facilitate electron tunneling, thereby improving photoelectric conversion efficiency of the cell.

In some implementations of this application, the silicon-based bottom layer 30 is an N-type silicon-based bottom layer. The electrode emission layer 20 is a boron-doped electrode emission layer. The doped polycrystalline silicon layer 50 is a phosphorus-doped polycrystalline silicon layer. A material of the tunneling oxide layer 40 includes at least one of silicon oxide, titanium oxide, and aluminum oxide. A material of the passivation layer 12 includes but is at least one of silicon oxide, silicon nitride, silicon oxynitride, and aluminum oxide. Materials of the first anti-reflection layer 11 and the second anti-reflection layer 60 are separately selected from at least one of silicon oxide, silicon nitride, and silicon oxynitride. In some embodiments, the passivation layer 12 is an aluminum oxide layer. Both the first anti-reflection layer 11 and the second anti-reflection layer 60 are silicon nitride layers. In some embodiments, a refractive index of the first anti-reflection layer 11 is different from a refractive index of the second anti-reflection layer 60. Materials of the first electrode 70 and the second electrode 80 are separately selected from metal materials such as silver and aluminum, but are not limited thereto.

In some implementations of this application, a thickness of the low-work-function conductive layer 90 is less than that of the doped polycrystalline silicon layer 50. In this case, it may be understood that the second electrode 80 runs through the second anti-reflection layer 60, and extends into the doped polycrystalline silicon layer 50 to be in direct contact with the low-work-function conductive layer 90. In this way, the second electrode 80 may collect electrons from the low-work-function conductive layer 90, and may directly collect electrons from the doped polycrystalline silicon layer 50, which can be more efficient. In addition, the low-work-function conductive layer 90 is embedded in the doped polycrystalline silicon layer 50, so that the low-work-function conductive layer 90 can be prevented from being oxidized and corroded, thereby potentially prolonging a service life of the solar cell. That the low-work-function conductive layer 90 is embedded in the doped polycrystalline silicon layer 50 means that parts that are of a surface of the low-work-function conductive layer 90 and that are not in contact with the second electrode 80 and the tunneling oxide layer 40 are all surrounded by the material of the doped polycrystalline silicon layer 50.

In some implementations of this application, the thickness of the low-work-function conductive layer 90 ranges from about 2 nm to about 100 nm. For example, the thickness of the low-work-function conductive layer 90 may be about 2 nm, 5 nm, 8 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, or 100 nm. The thickness of the low-work-function conductive layer 90 is controlled within the foregoing range, so that a burnthrough risk caused by the high-temperature metal paste during cell preparation can be reduced, a yield can be increased, and a high photoelectric conversion rate can be achieved.

In some implementations of this application, the low-work-function conductive layer 90 is in direct contact with the tunneling oxide layer 40. That is, the low-work-function conductive layer 90 extends in the direction from the surface of the tunneling oxide layer 40 to the second electrode 80. In some embodiments, the low-work-function conductive layer 90 extends in the direction from the surface of the tunneling oxide layer 40 to the second electrode 80, and the thickness thereof is less than the thickness of the doped polycrystalline silicon layer 50. The second electrode 80 runs through the second anti-reflection layer 60, and extends into the doped polycrystalline silicon layer 50 and is in direct contact with the low-work-function conductive layer 90.

In some implementations of this application, an orthographic projection of the second electrode 80 in the first direction falls within the low-work-function conductive layer 90 and the orthographic projection of the second electrode 80 in the first direction overlaps the low-work-function conductive layer 90. The first direction points from the second anti-reflection layer 60 to the first anti-reflection layer 11. That is, the second electrode 80 is a patterned electrode (gate line), and a shape of the second electrode 80 is the same as a shape of the low-work-function conductive layer 90. In this embodiment of this application, the projection of the second electrode 80 in the first direction on the low-work-function conductive layer 90 coincides with the end surface that is of the low-work-function conductive layer 90 and that is away from the tunneling oxide layer 40. In some implementations of this application, a sidewall of the low-work-function conductive layer 90 is perpendicular to the tunneling oxide layer 40 (as shown in FIG. 1, a cross-sectional size of the low-work-function conductive layer 90 is uniform). However, the low-work-function conductive layer 90 is generally prepared by using an etching process. Considering etching precision, the sidewall of the low-work-function conductive layer 90 is not necessarily perpendicular to the tunneling oxide layer 40. Referring to FIG. 2, the cross-sectional size of the low-work-function conductive layer 90 gradually increases in a direction from the doped polycrystalline silicon layer 50 to the tunneling oxide layer 40 (that is, the sidewall thereof is not perpendicular to the tunneling oxide layer 40, and the sidewall thereof may be a plane or a curved surface). It should be noted that a cross section of the low-work-function conductive layer 90 refers to a cross section obtained by truncating the low-work-function conductive layer 90 along a plane parallel to the tunneling oxide layer 40. In this case, that the orthographic projection of the second electrode 80 overlaps the low-work-function conductive layer may be understood as that the orthographic projection of the second electrode 80 overlaps a first surface of the low-work-function conductive layer 90, and the first surface thereof is a surface that is of the low-work-function conductive layer 90 and that faces away from the tunneling oxide layer 40. In this embodiment of this application, the projection of the second electrode 80 in the first direction on the low-work-function conductive layer 90 coincides with a plane that is of the low-work-function conductive layer 90 and that is away from the tunneling oxide layer 40.

In some implementations, referring to FIG. 3, the orthographic projection of the second electrode 80 in the first direction falls within the low-work-function conductive layer 90, and there is a distance between an edge of the orthographic projection of the second electrode 80 in the first direction and an edge of the low-work-function conductive layer 90. The first direction points from the second anti-reflection layer 60 to the first anti-reflection layer 11. In this way, the low-work-function conductive layer 90 can bear the electrode paste to prevent the doped polycrystalline silicon layer 50 from being burnt through. In this case, the sidewall of the low-work-function conductive layer 90 may be perpendicular to the tunneling oxide layer 40 or not perpendicular to the tunneling oxide layer 40. In this embodiment of this application, the edge of the projection of the second electrode 80 in the first direction on the low-work-function conductive layer 90 is spaced from an edge of the plane that is of the low-work-function conductive layer 90 and that is away from the tunneling oxide layer 40.

In some other implementations, referring to FIG. 4, considering preparation precision, the low-work-function conductive layer 90 may alternatively fall within the orthographic projection of the second electrode 80 in the first direction and the distance between the edge of the low-work-function conductive layer 90 and the edge of the orthographic projection of the second electrode 80 is less than or equal to about 10 μm. In this embodiment of this application, the projection of the second electrode 80 in the first direction on the plane in which the end surface that is of the low-work-function conductive layer 90 and that is away from the tunneling oxide layer 40 is located covers the end surface that is of the low-work-function conductive layer 90 and that is away from the tunneling oxide layer 40, and has an area greater than that of the end surface that is of the low-work-function conductive layer 90 and that is away from the tunneling oxide layer 40. In addition, a distance between the projection and an edge of the end surface that is of the low-work-function conductive layer 90 and that is away from the tunneling oxide layer 40 is less than or equal to about 10 μm. For example, the foregoing distance may be about 0.1 μm, 0.2 μm, 0.5 μm, 1 μm, 1.5 μm, 2 μm, 2.5 μm, 3 μm, 4 μm, 5 μm, 6 μm, 7μm, 8 μm, 9 μm, or 9.5 μm. It should be noted that, when the cross-sectional size of the low-work-function conductive layer 90 gradually increases in the direction from the doped polycrystalline silicon layer 50 to the tunneling oxide layer 40, the foregoing case means that a distance between an edge of the first surface of the low-work-function conductive layer 90 (the first surface thereof is the surface that is of the low-work-function conductive layer 90 and that faces away from the tunneling oxide layer 40) and the edge of the orthographic projection of the second electrode 80 is less than or equal to about 10 μm. Because the distance between the edge of the low-work-function conductive layer 90 and the edge of the orthographic projection of the second electrode 80 is less than or equal to about 10 μm, a risk that the high-temperature electrode paste burns through the doped polycrystalline silicon layer 50 during cell preparation is low. Therefore, the problem that the electrode paste burns through the doped polycrystalline silicon layer 50 can be potentially alleviated, and the second electrode 80 may directly collect electrons from the doped polycrystalline silicon layer 50. In this case, the sidewall of the low-work-function conductive layer 90 may be perpendicular to the tunneling oxide layer 40 or not perpendicular to the tunneling oxide layer 40.

It should be noted that, in FIG. 1 to FIG. 4 of this application, the first anti-reflection layer 11, the passivation layer 12, and the electrode emission layer 20 are in a wavy shape, to conform to a pyramidal light-trapping structure formed on a side surface (a front surface) of the silicon-based bottom layer through a texturing process. The wavy shape is a common illustration pattern in the art, and sets no limitation on forms of the first anti-reflection layer 11, the passivation layer 12, and the electrode emission layer 20 in this application.

In some implementations of this application, a work function of the low-work-function conductive layer 90 ranges from about 2.7 eV to about 3.9 eV. The work function refers to “minimum energy required to move an electron from inside a solid just to a surface of the object”. For example, the work function of the low-work-function conductive layer 90 may be but is about 2.7 eV, 2.8 eV, 2.9 eV, 3.0 eV, 3.1 eV, 3.2 eV, 3.3 eV, 3.4 eV, 3.5 eV, 3.6 eV, 3.7 eV, 3.8 eV, or 3.9 eV.

In some implementations of this application, a material of the low-work-function conductive layer 90 is selected from a metal material. In some implementations, the material of the low-work-function conductive layer 90 is selected from at least one of Ca, Mg, Ba, Ga, Li, Ce, Tb, Gd, Y, Nd, Lu, Th, Sc, La, U, and Hf.

In some implementations of this application, a thickness of the tunneling oxide layer 40 is less than or equal to about 2 nm. For example, the thickness is about 0.5 nm, 1.0 nm, 1.5 nm, or 2.0 nm.

In some implementations of this application, thicknesses of the first anti-reflection layer 11 and the second anti-reflection layer 60 separately range from about 10 nm to about 120 nm. The thicknesses of the first anti-reflection layer 11 and the second anti-reflection layer 60 are controlled within the foregoing range to facilitate performance of the cell and control a total thickness of the solar cell to be small. For example, the thicknesses of the first anti-reflection layer 11 and the second anti-reflection layer 60 may be separately about 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, or 115 nm.

In some implementations of this application, a thickness of the passivation layer 12 ranges from about 5 nm to about 20 nm. The thickness of the passivation layer 12 is controlled within the foregoing range, to achieve a passivation effect, and control the total thickness of the solar cell to be within a range. For example, the thickness of the passivation layer 12 may be about 5 nm, 8 nm, 10 nm, 12 nm, 15 nm, or 20 nm.

In an embodiment, the solar cell includes a first anti-reflection layer 11 (for example, a silicon nitride layer with a thickness of about 80 nm), a passivation layer 12 (for example, an aluminum oxide layer with a thickness of about 12 nm), an electrode emission layer 20, a silicon-based bottom layer 30 (for example, an N-type silicon-based bottom layer with a thickness of 130 μm), a tunneling oxide layer 40 (for example, a silicon oxide layer with a thickness of 1.6 nm), a doped polycrystalline silicon layer 50 (specifically, a phosphorus-doped polycrystalline silicon layer with a thickness of about 100 nm and sheet resistance of about 40 Ω/sqr), and a second anti-reflection layer 60 (for example, a silicon nitride layer with a thickness of about 80 nm), which are sequentially stacked. A low-work-function conductive layer 90 with a thickness of about 50 nm is provided in the doped polycrystalline silicon layer 50, and extends in a direction from a surface of the tunneling oxide layer 40 to the second anti-reflection layer 60. A first electrode 70 and a second electrode 80 are respectively provided on the first anti-reflection layer 11 and the second anti-reflection layer 60. The second electrode 80 runs through the second anti-reflection layer 60 and is in direct contact with the low-work-function conductive layer 90, and a pattern of the second electrode 80 is the same as a shape of the low-work-function conductive layer 90.

In some implementations of this application, preparation of the solar cell may include the following steps:
S01: Preprocess a silicon wafer raw material.
S02: Form an electrode emission layer on a side surface (a front surface) of the silicon wafer, and polish a back surface of the silicon wafer, to obtain the electrode emission layer and a silicon-based bottom layer.
S03: Deposit a tunneling oxide layer on the back surface of the silicon wafer.
S04: Deposit a prefabricated low-work-function conductive layer on the tunneling oxide layer.
S05: Prepare a mask layer on the prefabricated low-work-function conductive layer, etch a low-work-function metal layer in a non-mask region through, and remove the mask layer, to obtain a low-work-function conductive layer, where in some implementations, a pattern of the mask is consistent with a pattern of a preset second electrode.
S06: Continue to form a doped non-crystalline silicon film, and then perform high-temperature crystallization and annealing to obtain a doped polycrystalline silicon layer, where in some specific embodiments, the doped polycrystalline silicon layer is a phosphorus-doped polycrystalline silicon layer.
S07: Prepare a passivation layer on a surface of the electrode emission layer.
S08: Prepare a first anti-reflection layer on a surface of the passivation layer, and provide a second anti-reflection layer on a surface that is of the doped polycrystalline silicon layer and that faces away from the tunneling oxide layer.
S09: Separately prepare a first electrode and a second electrode by using a printing process, to obtain the solar cell. An electrode paste is separately printed on surfaces of the first anti-reflection layer and the second anti-reflection layer, and then high-temperature sintering is performed, to obtain the first electrode and the second electrode. In some specific embodiments, the foregoing printing is screen printing.

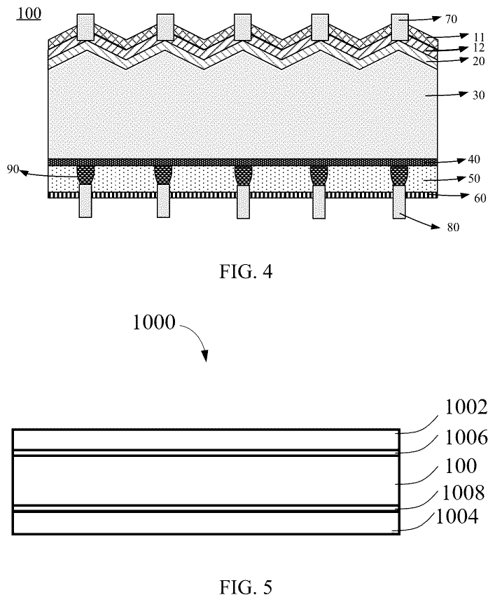

An embodiment of this application further provides a photovoltaic module 1000, including the solar cell provided in the embodiments of this application. Referring to FIG. 5, the photovoltaic module 1000 further includes a front cover plate 1002, a rear cover plate 1004, a first encapsulant film 1006, and a second encapsulant film 1008. The front cover plate 1002 is bonded to a side of the solar cell 100 by using the first encapsulant film 1006. The rear cover plate 1004 is bonded to another side of the solar cell 100 by using the second encapsulant film 1008. With the solar cell provided in this application, the photovoltaic module 1000 has high market competitiveness.

The foregoing descriptions are example implementations of this application. It should be noted that a person of ordinary skill in the art can make improvements and modifications to this application without departing from the principles of this application, and the improvements and modifications fall within the protection scope of this application.

1. A solar cell, comprising a first anti-reflection layer, a passivation layer, an electrode emission layer, a silicon-based bottom layer, a tunneling oxide layer, a doped polycrystalline silicon layer, and a second anti-reflection layer, which are stacked, wherein a first electrode and a second electrode are respectively provided on the first anti-reflection layer and the second anti-reflection layer; and
a low-work-function conductive layer is provided in the doped polycrystalline silicon layer, and the low-work-function conductive layer is adjacent to the second electrode.

2. The solar cell according to claim 1, wherein a thickness of the doped polycrystalline silicon layer ranges from 10 nm to 120 nm.

3. The solar cell according to claim 1, wherein a thickness of the low-work-function conductive layer is less than a thickness of the doped polycrystalline silicon layer.

4. The solar cell according to claim 1, wherein the thickness of the low-work-function conductive layer ranges from 2 nm to 100 nm.

5. The solar cell according to claim 1, wherein a projection of the second electrode in a first direction on a plane in which an end surface that is of the low-work-function conductive layer and that is away from the tunneling oxide layer is located falls within the end surface that is of the low-work-function conductive layer and that is away from the tunneling oxide layer; and
the first direction points from the second anti-reflection layer to the first anti-reflection layer.

6. The solar cell according to claim 5, wherein the projection of the second electrode in the first direction on the plane in which the end surface that is of the low-work-function conductive layer and that is away from the tunneling oxide layer is located substantially coincides with the end surface that is of the low-work-function conductive layer and that is away from the tunneling oxide layer.

7. The solar cell according to claim 1, wherein the low-work-function conductive layer is adjacent to the tunneling oxide layer.

8. The solar cell according to claim 1, wherein a material of the low-work-function conductive layer is selected from Ca, Mg, Ba, Ga, Li, Ce, Tb, Gd, Y, Nd, Lu, Th, Sc, La, U, or Hf.

9. The solar cell according to claim 1, wherein the silicon-based bottom layer is an N-type silicon-based bottom layer, and the doped polycrystalline silicon layer is a phosphorus-doped polycrystalline silicon layer.

10. The solar cell according to claim 1, wherein the second electrode runs through the second anti-reflection layer and protrudes relative to a surface that is of the second anti-reflection layer and that faces away from the doped polycrystalline silicon layer.

11. The solar cell according to claim 1, wherein the second electrode runs through the second anti-reflection layer, and extends into the doped polycrystalline silicon layer and is adjacent to the low-work-function conductive layer.

12. The solar cell according to claim 1, wherein a material of the tunneling oxide layer comprises at least one of silicon oxide, titanium oxide, or aluminum oxide.

13. The solar cell according to claim 1, wherein a material of the passivation layer comprises at least one of silicon oxide, silicon nitride, silicon oxynitride, or aluminum oxide.

14. The solar cell according to claim 1, wherein a material of the first anti-reflection layer comprises at least one of silicon oxide, silicon nitride, or silicon oxynitride; and a material of the second anti-reflection layer comprises at least one of silicon oxide, silicon nitride, or silicon oxynitride.

15. A photovoltaic module, wherein the photovoltaic module comprises the solar cell according to claim 1.

16. The photovoltaic module according to claim 15, wherein the photovoltaic module further comprises a front cover plate, a rear cover plate, a first encapsulant film, and a second encapsulant film, the front cover plate is bonded to a side of the solar cell by using the first encapsulant film, and the rear cover plate is bonded to another side of the solar cell by using the second encapsulant film.
